(19) United States
(12) Patent Application Publication
(10) Pub. No.: US 2002/0050846 A1
(43) Pub. Date: May 2, 2002

(54) Method and device for eliminating time delay of an inverted signal

(76) Inventor: Yu-Wei Lin, Taipei (TW)

Correspondence Address: RABIN & CHAMPAGNE, PC, 1101 14TH STREET, NW, SUITE 500, WASHINGTON, DC, 20005, US

(21) Appl. No.: 09/973,551

(22) Filed: Oct. 9, 2001

(30) Foreign Application Priority Data
Oct. 23, 2000 (TW) 89122273

(51) Int. Cl. H03K 3/037

(52) U.S. Cl. 327/218

(57) ABSTRACT

A method and device for eliminating a time delay of an inverted signal is disclosed. A data signal is fed to a first flip-flop. The data signal is inverted and then the inverted data signal is fed to a second flip-flop. The first and the second flip-flops are triggered simultaneously. Therefore, a first output signal is outputted from the first flip-flop, and a second output signal is outputted from the second flip-flop, wherein the first output signal is an inverted signal of the second output signal without time delay.

This application incorporates by reference Taiwanese application Ser. No. 89122273, filed Oct. 23, 2000.

### BACKGROUND OF THE INVENTION

1. Field of the Invention

The present invention relates to a logic design method and a device thereof; more particularly, relates to a method and device for resulting a pair of divide-by two clock signals with exact 180 degree phase shift each other.

2. Description of the Related Art

Technology develops faster and faster these days. Because of the highly developed technology of integrated circuits, electronic products become more compact and more powerful than ever. Inverters are widely used for inverting a signal for obtaining a signal with reverse phase in the design of digital circuits.

FIG. 1A is an illustration of a prior art simulation model obtaining a signal and its inverted signal. As shown, a signal Q is inverted by an inverter 110 to generate an inverted signal Q′. However, the inverter 110 needs time to invert the signal Q and therefore there is a time delay “t” between the signal Q and the actual inverted signal Qt′, as shown in FIG. 1B.

FIG. 1B (Prior Art) is a timing diagram of a prior art according to an aspect of FIG. 1. Theoretically, the inverted signal Q′ is generated by following the signal Q. If no operation time exists, the transient time points of the signal Q and Q′ are the same, as indicated by the dashed line. However, the inverter 110 needs time to function, the actual output waveform of the inverted signal is Qt′, having a different transient time point from that of the signal Q by a time interval t. Namely, the inverted signal Qt′ is transient until time t is passed from the transient time point of the signal Q. The time interval t is the operation time of the inverter.

On the other hand, time delay also occurs using a flip-flop to obtain a signal and its inverted signal. Referring to FIG. 2A, it shows a symbol of a D-type flip-flop 200 having a terminal D for receiving a data signal, a terminal CK for receiving a clock signal, a terminal Q for outputting the data signal and a terminal Q′ for outputting the inverted data signal. The D-type flip-flop can be triggered at a positive or negative edge of the clock signal CK for outputting the data signal Q having the same phase as it is received at the terminal D, and for outputting the inverted data signal Q′. As shown in FIG. 2B, the inverted data signal is obtained by inputting the data signal Q into an inverter. Therefore, a time delay exists between the data signal Q and the inverted data signal Q′ during output status transition, as shown in FIG. 1B.

The time delay also occurs for other flip-flop types. FIG. 3 shows various symbols of different flip-flops. As shown in FIG. 3, the T-type flip-flop 310, the RS flip-flop 320 and the JK flip-flop have an output terminal Q′ and another output terminal Q′ for outputting a signal inverted from Q. However, because an inverter is connected between the terminals Q and Q′, a time delay t unavoidably exists between the data signal Q and the inverted data signal Q′ during output status transition.

In practical application, it might need a number of pulses having different phases to form a pulse group for data sequential sampling. For example, 10 pulses each having the same frequency 125 MHz are combined to a pulse group. Referring to FIG. 4, if the time delay for two adjacent pulses is 0.8 ns, ten pulses appear in turns within one period (0.8 ns) and the time intervals for each of two adjacent pluses are equal, i.e., 0.8 ns. Referring to FIG. 4, pulse group S is combined by ten pulses each of which has different phase. Each of the ten pulses has a frequency of 125 MHz, and a time delay of 0.8 ns exists between two adjacent pulses. For simplicity, only the rising edge of each pulse in the pulse group S is depicted.

In practice, in order to obtain a pulse with a frequency of 125 MHz, a phase locked loop (PLL) is used for generating a pulse with a frequency of 250 MHz and then the frequency of pulse is divided by 2 by a frequency divider for getting a well-behavior duty cycle. Following is an example how to combine a pulse group S from 10 pulses having a frequency of 125 MHz respectively. As shown in FIG. 4, five pulses, which each has a frequency of 250 MHz and a time delay of 0.8 ns between two adjacent pulses, are fetched from five different phases of a voltage control oscillator (VCO) of the PLL. Dividing the frequency of each pulse by 2 by the frequency divider, five pulses having a frequency of 125 MHz and intervals of 0.8 ns. The other pulses can be obtained by inverting the previous five pulses, which is described in detail as follows.

Referring to FIG. 5, the pulse group S comprises 10 pulses each of which has a different phase from one another and the same frequency of 125 MHz. For obtaining the pulse group S, the VCO or PLL first generates a pulse group P comprising five pulses CK0, CK1, CK2, CK3, and CK4, each having the same frequency of 250 MHz and a time interval of 0.8 ns existing between two adjacent pulses. In the drawing, the real lines represent rising edges of the pulses and the dash lines represent falling edges of the pulses.

Next, by the frequency divider, the pulse group P is converted to a pulse group Pa, in which each pulse a frequency of 125 MHz and an interval of 0.8 ns between two pulses. As shown, the five pulses in the pulse group Pa comply with requirements of pulses CK0, CK1, CK2, CK3 and CK4 in the pulse group S. Therefore, the pulses CK0˜CK4 in the pulse group Pa can serve as the pulses CK0˜CK4 in the pulse group S.

After the previous five pulses are obtained, the other five pulses can be obtained by inverting the pulses CK0, CK1, CK2, CK3 and CK4. Namely, by inverting the pulse group Pa, the other five pulses CK5, CK6, CK7, CK8 and CK9 in the pulse group S can thus be obtained. As shown, a pulse group Pb is obtained by inverting the pulse group Pa. In the pulse group Pb, the phase of pulse CK0 is the same as the phase of pulse CK 5 in the group S. In addition, the phases of the pulses CK1, CK2, CK3 and CK4 in the group Pb are the same as those of the pulses CK6, CK7, CK8 and CK9 in the pulse group S. Accordingly, the pulse group Pb, by inverting the pulse group Pa, complies with requirements of the pulses CK5, CK6, CK7, CK8 and CK9 in the pulse group S. Namely, the pulses CK0, CK1, CK2, CK3 and CK4 in the pulse group Pb can be served as the pulses CK5, CK6, CK7, CK8 and CK9 in the pulse group S. Then, the pulse group S can be formed by combining the pulse groups Pa and Pb.

Practically, the frequency divider (divided by 2) can be implemented using a general D-type flip-flop. However, as mentioned above, an inverter exists between the S output and its complementary output of the D-type flip-flop, i.e., a delay time exists across the inverter. Therefore, if the delay time occurs when the pulse group Pa is inverted to form the pulse group Pb, then the pulses in pulse group Pb are delayed such that those pulses can not comply with the requirements of the pulse group S. It should eliminate the time delay due to the inverter if the intervals for each two adjacent pulses in the pulse group S requires as equal as possible.

### SUMMARY OF THE INVENTION

Accordingly, it is a major objective of the present invention to provide a method and device for eliminating a time delay of an inverted signal, for obtaining an inverted data signal of its corresponding data signal without time delay.

According to the object of the invention, the invention provides a method and device for eliminating a time delay of an inverted signal. A data signal is fed to a first flip-flop. The data signal is inverted and then the inverted data signal is fed to a second flip-flop. The first and the second flip-flops are triggered simultaneously. Therefore, a first output signal is outputted from the first flip-flop, and a second output signal is outputted from the second flip-flop, wherein the first output signal is an inverted signal of the second output signal without time delay.

Other embodiments of the present invention will be evident from the description and drawings.

### BRIEF DESCRIPTION OF THE DRAWINGS

Other objects, features, and advantages of the invention will become apparent from the following detailed description of the preferred but non-limiting embodiments. The description is made with reference to the accompanying drawings in which:

FIG. 1A is an illustration of a prior art simulation model obtaining a signal and its inverted signal;

FIG. 1B is a timing diagram of a prior art according to an aspect of the FIG. 1;

FIG. 2A is a schematic of a prior art showing a D-type flip-flop;

FIG. 2B is a schematic of a prior art showing an inverter connected between the signal and its inverted output;

FIG. 3 shows various symbols representing various flip-flops;

FIG. 4 is a sketch of prior art showing a pulse signal group;

FIG. 5 shows a schematic diagram for grouping a sampled pulse signal group; and

FIG. 6 is a schematic diagram for illustrating a device for eliminating a time delay between an inverted data signal and its corresponding data signal according to one preferred embodiment of the invention.

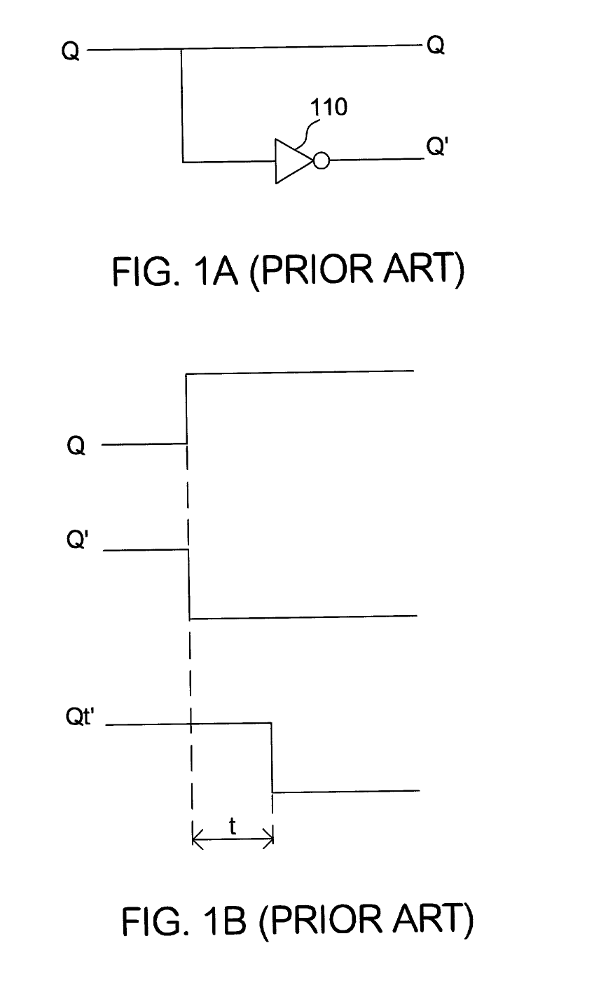

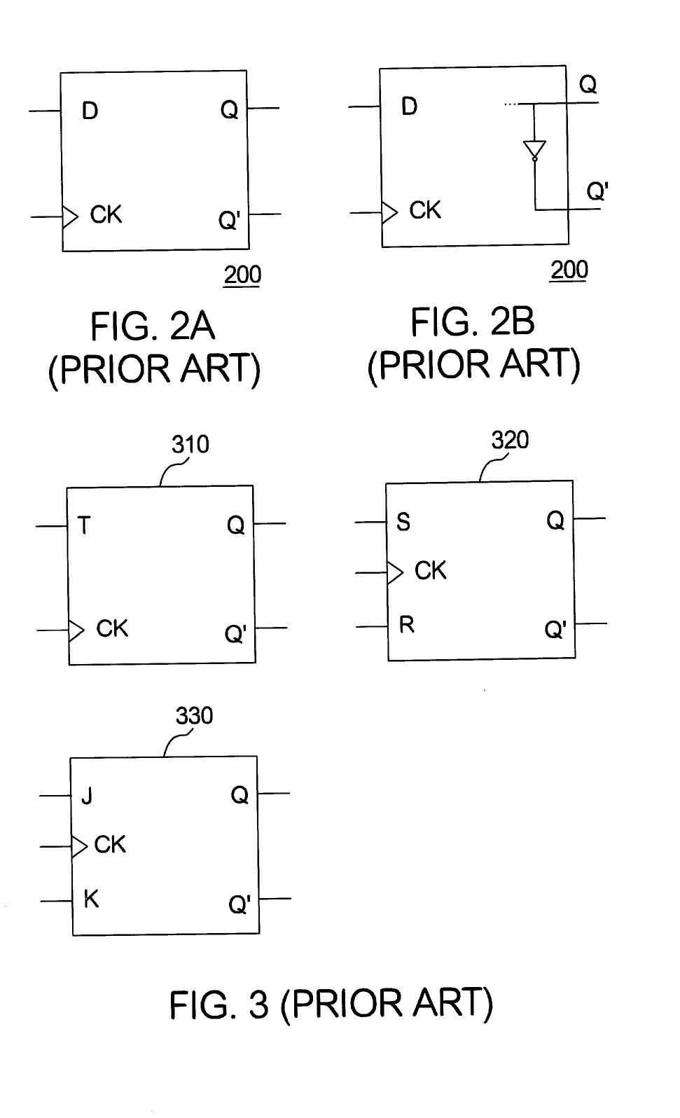

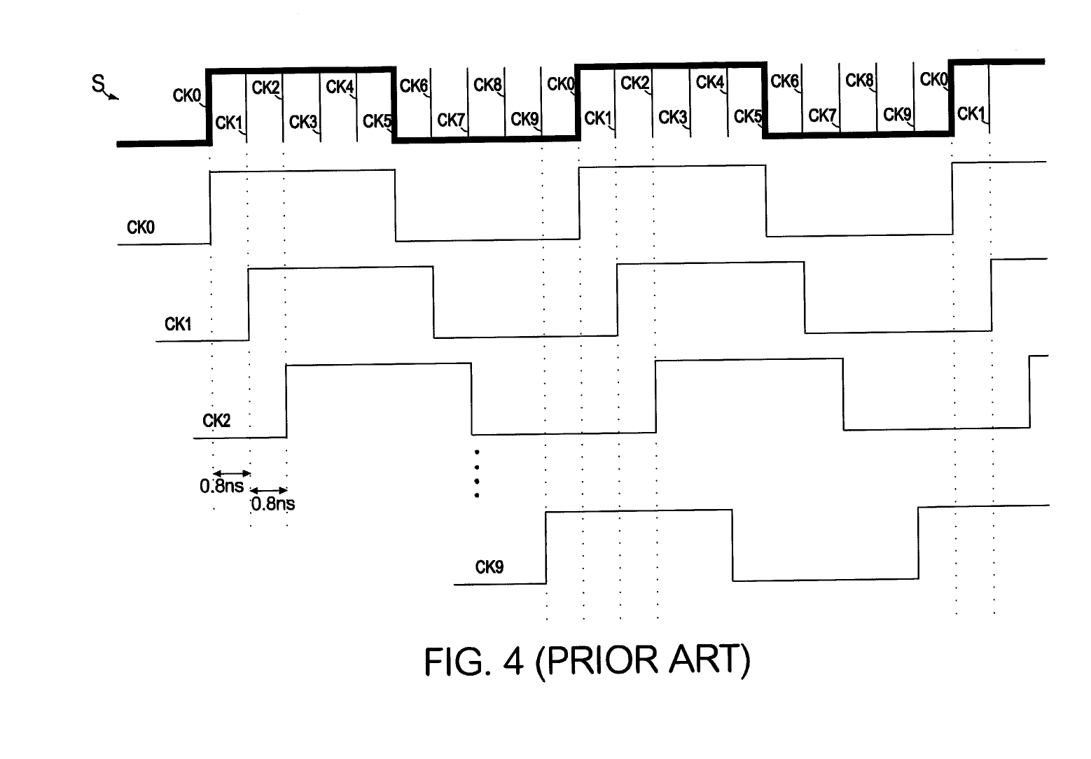

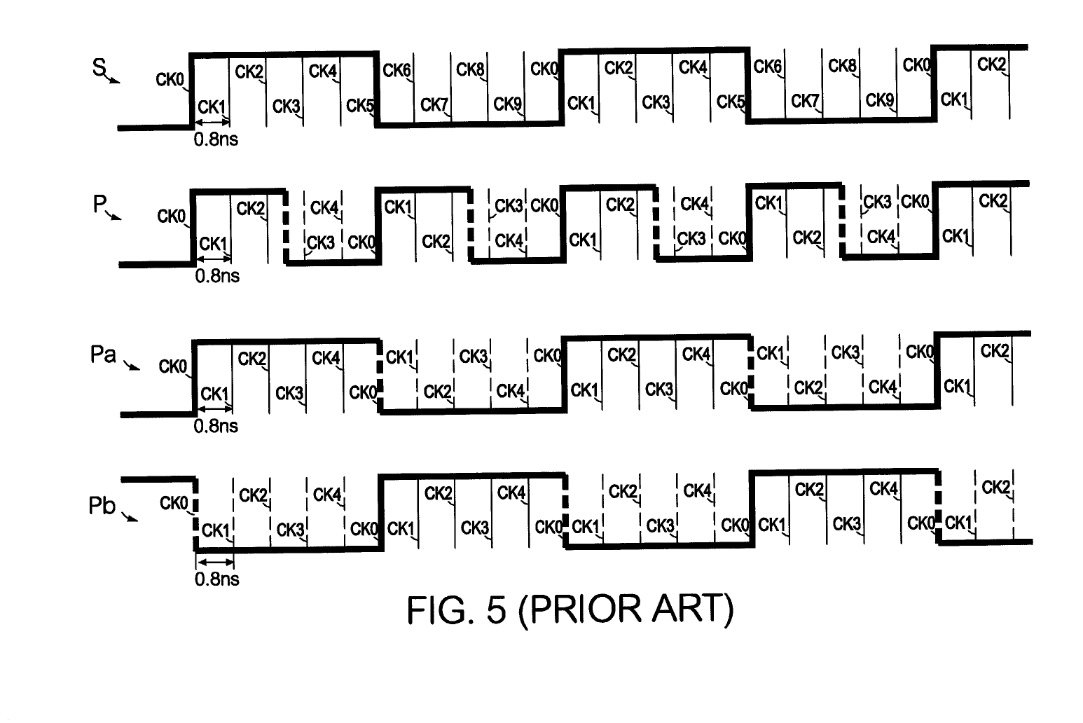

Corresponding numerals and symbols in the different figures and tables refer to corresponding parts unless otherwise indicated.

### DESCRIPTION OF THE PREFERRED EMBODIMENTS

Aspects of the present invention include methods and apparatus for designing an integrated circuit. In the following description, specific information is set forth to provide a thorough understanding of the present invention. Well-known circuits and devices are included in schematic diagram form in order to not to complicate the description unnecessarily. Moreover, it will be apparent to one skill in the art that specific details of these schematics are not required in order to practice the present invention.

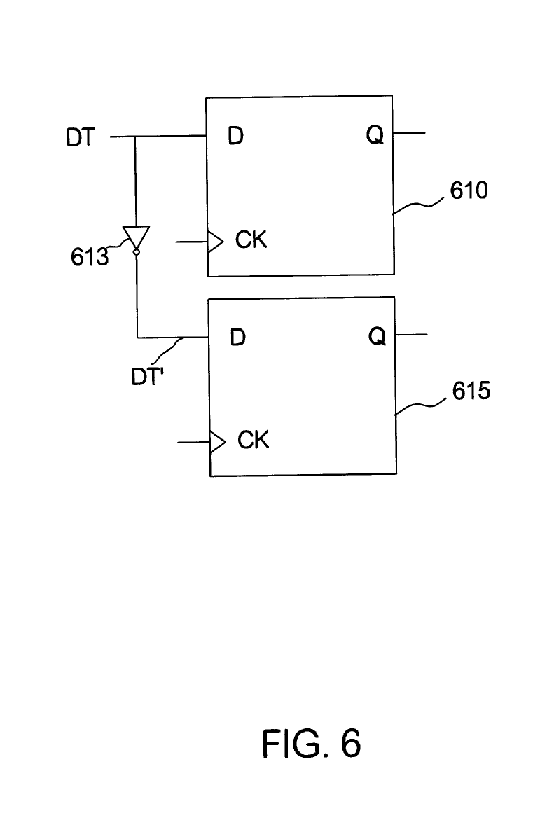

FIG. 6 is a schematic diagram for illustrating a device for eliminating a time delay between an inverted data signal and its corresponding data signal according to one preferred embodiment of the invention. As shown, flip-flops 610 and 615 are D-type flip-flops for example, having an input terminal D, an output terminal Q and a clock terminal CK respectively.

The flip-flops 610, 615 are triggered when a clock is applied to the clock terminals CK. A data signal DT is directly fed to the input terminal D of the flip-flop 610. An inverter 613 is coupled between the input terminals D of the flip-flops 610, 615. Due to the inverter 613, the data signal DT is inverted to an inverted data signal DT′ and then fed to the input terminal D of the flip-flop 615.

When the clock is applied to the clock terminals CK of both flip-flops 610, 615, the flip-flops 610, 615 are triggered simultaneously. Accordingly, the data signal DT is outputted from the output terminal Q of the flip-flop 610, and at the same time the inverted data signal DT′ is outputted without a time delay from the output terminal Q of the flip-flop 615 to the data signal DT.

It should be noted that the D-type flip-flop is not the only for implanting the invention. Those skilled in the art can use other type flip-flop, such as a T-type, RS, JK or their combination, to modify the embodiment above.

According to the method or device for eliminating a time delay of an inverted signal of the invention, it can effectively eliminate the time delay between an inverted data signal and its corresponding signal. Therefore, the invention can overcome various circuit design obstructions due to the time delay between the inverted data signal and its data signal, thereby the overall performance can be increased.

While the invention has been described by way of example and in terms of the preferred embodiment, it is to be understood that the invention is not limited to the disclosed embodiment. To the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method for eliminating a time delay of an inverted signal, comprising steps of:
providing a data signal;
feeding the data signal to a first flip-flop;
inverting the data signal and then feeding the inverted data signal to a second flip-flop; and
outputting a first output signal from the first flip-flop, and a second output signal from the second flip-flop, wherein the first output signal is a inverted signal of the second output signal.

2. The method of claim 1, wherein the first flip-flop is a D-type flip-flop.

3. The method of claim 1, wherein the second flip-flop is a D-type flip-flop.

4. The method of claim 1, wherein the first flip-flop is a T-type flip-flop.

5. The method of claim 1, wherein the second flip-flop is a T-type flip-flop.

6. A method for eliminating a time delay of an inverted signal, comprising steps of:
providing a data signal;
feeding the data signal to a first flip-flop;
inverting the data signal and then feeding the inverted data signal to a second flip-flop;
triggering the first and the second flip-flops simultaneously; and
outputting a first output signal from the first flip-flop, and a second output signal from the second flip-flop, wherein the first output signal is a inverted signal of the second output signal.

7. The method of claim 6, wherein the first flip-flop is a D-type flip-flop.

8. The method of claim 6, wherein the second flip-flop is a D-type flip-flop.

9. The method of claim 6, wherein the first flip-flop is a T-type flip-flop.

10. The method of claim 6, wherein the second flip-flop is a T-type flip-flop.

11. A device for eliminating a time delay of an inverted signal, comprising:
a first flip-flop, having a first input terminal coupled to a data signal;
an inverter, coupled to the first input terminal for inverting the data signal to an inverted data signal; and
a second flip-flop, having a second input terminal coupled to an output of the inverter, for receiving the inverted data signal, wherein the first flip-flop outputs the data signal and the second flip-flop outputs the inverted data signal.

12. The method of claim 11, wherein the first flip-flop is a D-type flip-flop.

13. The method of claim 11, wherein the second flip-flop is a D-type flip-flop.

14. The method of claim 11, wherein the first flip-flop is a T-type flip-flop.

15. The method of claim 11, wherein the second flip-flop is a T-type flip-flop.

16. The method of claim 11, wherein the first flip-flop is a RS flip-flop.

17. The method of claim 11, wherein the second flip-flop is a RS flip-flop.

18. The method of claim 11, wherein the first flip-flop is a JK flip-flop.

19. The method of claim 11, wherein the second flip-flop is a JK flip-flop.
